(19) United States
(12) Patent Application Publication
(10) Pub. No.: US 2008/0210155 A1
(43) Pub. Date: Sep. 4, 2008

(54) SILICON SINGLE CRYSTAL AND PROCESS FOR PRODUCING IT

(75) Inventors: Dirk Dantz, Burghausen (DE); Wilfried Von Ammon, Hockburg/Ach (AT); Dirk Zemke, Marktl (DE); Franz Segieth, Kirchham (DE)

Correspondence Address: BROOKS KUSHMAN P.C., 1000 TOWN CENTER, TWENTY-SECOND FLOOR, SOUTHFIELD, MI, 48075, US

(73) Assignee: SILTRONIC AG, Munich (DE)

(21) Appl. No.: 12/039,351

(22) Filed: Feb. 28, 2008

Related U.S. Application Data
(62) Division of application No. 10/351,739, filed on Jan. 27, 2003, now abandoned.

(30) Foreign Application Priority Data
Feb. 7, 2002 (DE) 10205085.6

(51) Int. Cl. C30B 15/00

(52) U.S. Cl. 117/13

(57) ABSTRACT

A silicon single crystal which has been produced using the Czochralski method has a <113> orientation.

### BACKGROUND OF THE INVENTION

1. Field of the Invention

The present invention relates to a silicon single crystal with a <113> orientation and to a process for producing a single crystal of this type.

2. The Prior Art

The <113> orientation, in addition to the <100> and <111> orientations, is among the silicon crystal orientations which have been researched most thoroughly. The corresponding (113) face has a low surface energy, thermal stability and belongs to the atomically smooth surfaces of this element. According to DE 196 15 291 C2, therefore, it is suitable as a substrate surface for epitaxial coatings.

(113) orientation surfaces have hitherto been prepared from single crystals of different orientations, for example cut or etched out of <100> orientation single crystals. The <100> single crystals can be pulled using the known Czochralski method, in which a seed crystal is immersed in a silicon melt and slowly pulled upward with rotation. The single crystal crystallizes as a structure in ingot form which has two conical ends, of which the end known as the “body phase” is connected to a dash seed. The dash seed connects the seed crystal and the body phase and is distinguished by a small diameter, which is less than that of the seed crystal. It is necessary in order to terminate dislocations which are caused in the growing single crystal by stresses after the seed crystal has been applied to the melt.

### SUMMARY OF THE INVENTION

It is an object of the present invention to provide an advantageous process for producing <113> orientation silicon single crystals.

The above object is achieved according to the present invention by providing a process for producing a silicon single crystal with a <113> orientation, the silicon crystal being pulled using the Czochralski method in the form of an ingot which is suspended from a dash seed and has two conical end pieces, one of which is connected to the dash seed.

A process for producing a <113> orientation silicon single crystal by using the Czochralski method does not form part of the prior art. This may be because, as the inventors of the present application have discovered, the attempt to pull a dislocation-free single crystal with a <113> orientation failed both using the abovementioned method and the standard process parameters.

Therefore, the present invention is also directed to a silicon single crystal which has been produced using the Czochralski method and has a <113> orientation.

The present invention is based on the discovery that particular circumstances have to be taken into account in order to be able to achieve the above object. For example, different growth rates of the different crystal faces ({100}, {111} and {113}), in particular the high growth rate of the {111} facet, have to be taken into account. On account of these differences, the dash seed of a <113> orientation single crystal tends to break out toward the side. In order to limit the resulting deviation in the immersed position of the seed crystal in the melt from the axis of rotation of the growing single crystal, it is proposed to reduce the length of the dash seed. This reduction in length is compared to the lengths which have hitherto been customary for pulling <100> orientation single crystals. Preferably, the length of the dash seed should not exceed 70 mm. In order to prevent the formation of dislocations in the growing single crystal despite the shorter dash seed, the diameter of the dash seed should likewise be selected to be smaller than is customary. It is preferable for the diameter of the dash seed at the narrowest point to be reduced to at least 5 mm, particularly preferably to at least 4 mm.

Furthermore, it is proposed to pull a body phase which is at least 30 mm longer than in a pulling process used to pull a <100> orientation silicon single crystal. This is in order to prevent {111} facets, in particular the central facet, from melting back, with the associated risk of dislocations being formed. It is preferable for the body phase to be lengthened by at least 60 mm, particularly preferably to be lengthened by 90 mm. Furthermore, in view of the risk of the {111} facets melting back, it is necessary to reduce the pulling rate, which is dependent on the furnace structure. It is therefore proposed for the pulling rate to be at most 90% of the rate at which a <100> orientation silicon single crystal can be pulled without dislocations in the same furnace. It is preferable for the final pulling rate during pulling of the section of the single crystal which is in ingot form to be limited to at most 85%, and particularly preferably to 80%.

The particularly preferred process parameters for the invention method are compared to those which are typical for the pulling of <100> orientation single crystals below with reference to figures.

### BRIEF DESCRIPTION OF THE DRAWINGS

Other objects and features of the present invention will become apparent from the following detailed description considered in connection with the accompanying drawings which disclose several embodiments of the present invention. It should be understood, however, that the drawings are designed for the purpose of illustration only and not as a definition of the limits of the invention. In the drawings:

FIG. 1 shows the diameter versus length for the dash seed;

FIG. 2 shows the diameter of the body phase (cone) as a function of the position of the ingot; and

FIG. 3 shows a comparison of the pulling rates after the pulling of the body phase as a function of the ingot position, using the same furnace structure.

### DETAILED DESCRIPTION OF PREFERRED EMBODIMENTS

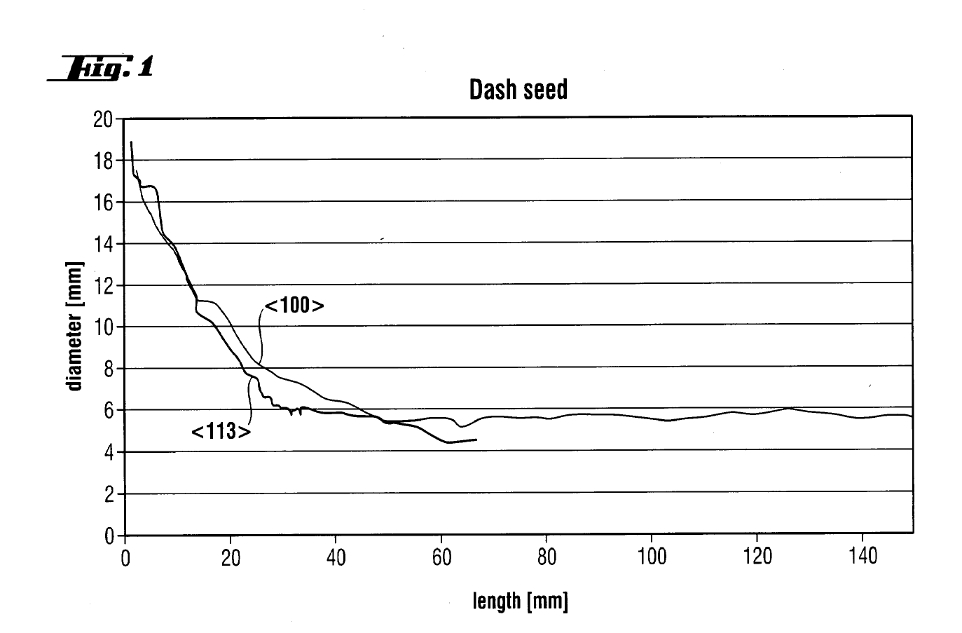

Turning now in detail to the drawings, FIG. 1 compares lengths and diameters of the dash seed. It can be seen that the length of the dash seed when <100> orientation single crystals are being pulled is longer, at 150 mm, as is the diameter at the narrowest point at approximately 5.5 mm.

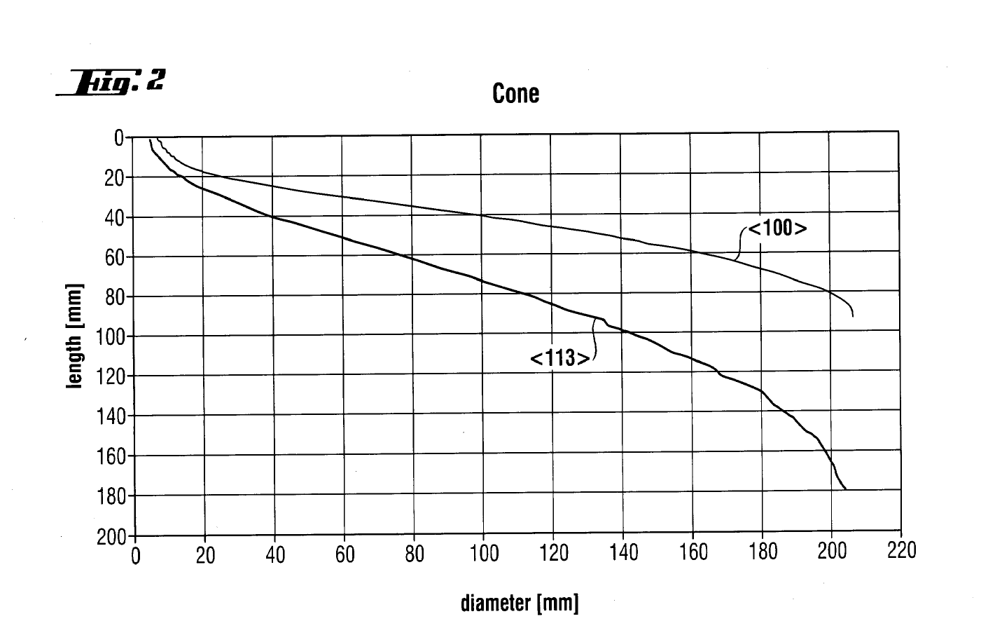

FIG. 2 compares the diameter of the body phase (cone) as a function of the position of the ingot. It can be seen that when <100> orientation single crystals are being pulled, the body phase is shorter, at approximately 90 mm.

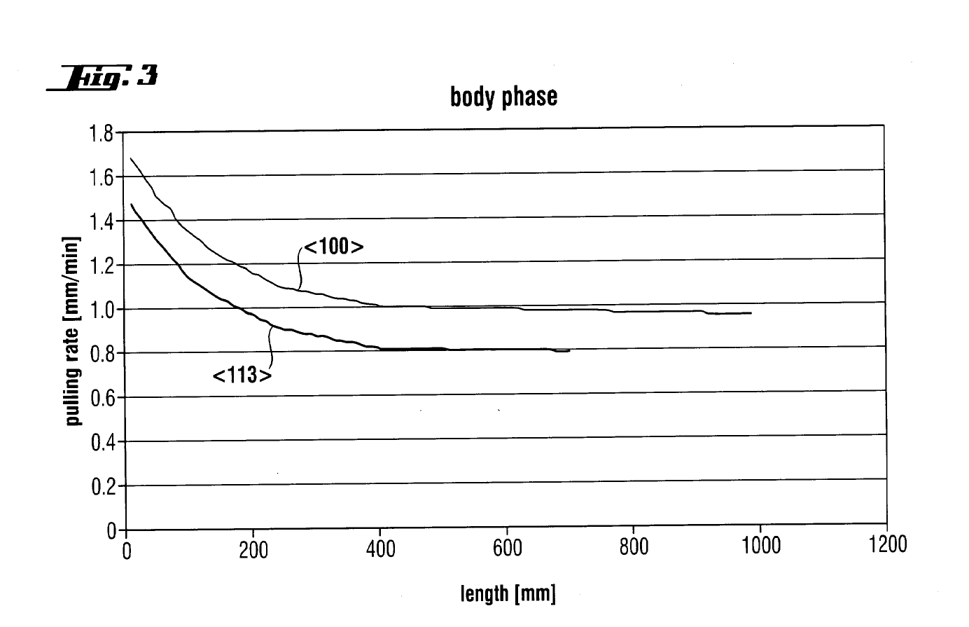

FIG. 3 shows a comparison of the pulling rates after the pulling of the body phase as a function of the ingot position, using the same furnace structure. It is clear that the final pulling rates are faster when <100> orientation single crystals are being pulled, at approximately 0.98 mm/min.

The single crystals which have been produced in accordance with the invention are processed further to form semiconductor wafers. They are supplied to manufacturers of electronic components as semiconductor wafers with one or two polished side faces, semiconductor wafers with an epitaxial coating or semiconductor wafers which have been coated in some other way. Also they can be supplied as semiconductor wafers, which have been subjected to a heat treatment which influences the distribution and size of grown-in defects.

Accordingly, while a few embodiments of the present invention have been shown and described, it is to be understood that many changes and modifications may be made thereunto without departing from the spirit and scope of the invention as defined in the appended claims.

1-3. (canceled)

4. A process for producing a silicon single crystal with a <113> orientation, comprising
pulling the silicon single crystal using a Czochralski method in the form of an ingot which is suspended from a dash seed and has two conical end pieces, and
one of said conical end pieces is connected to the dash seed.

5. The process as claimed in claim 4, comprising
pulling the silicon single crystal in a furnace with a pulling rate, and the pulling rate is at most 90% of a rate at which a <100> orientation silicon single crystal can be pulled without dislocations in the furnace.

6. The process as claimed in claim 4,
wherein the dash seed has a length of at most 70 mm and a diameter of at most 5 mm at its narrowest point, and the end piece which is connected to the dash seed is at least 30 mm longer than a corresponding end piece of a single crystal with a <100> orientation.

7. In a method for the production of semiconductor wafers which are selected from a group which includes semiconductor wafers with one or two polished side faces, semiconductor wafers with an epitaxial coating, semiconductor wafers which have been subjected to a heat treatment and semiconductor wafers which have been coated in some other way, the improvement which comprises
utilizing the silicon single crystal as claimed in claim 1 for said production.
